(19) United States
(12) Patent Application Publication
(10) Pub. No.: US 2026/0056458 A1
(43) Pub. Date: Feb. 26, 2026

(54) MASK AND MASK ASSEMBLY INCLUDING THE SAME

(71) Applicant: Samsung Display Co., Ltd., Yongin-si (KR)

(72) Inventor: SANGHA PARK, Yongin-si (KR)

(21) Appl. No.: 19/240,774

(22) Filed: Jun. 17, 2025

(30) Foreign Application Priority Data
Aug. 22, 2024 (KR) 10-2024-0112786

(51) Int. Cl. G03F 1/42; G03F 1/60

(52) U.S. Cl. CPC G03F 1/42; G03F 1/60

(57) ABSTRACT

A mask includes a center part extending in a first direction and including a cell region in which deposition openings are defined, and terminal parts spaced apart from each other in the first direction with the center part therebetween, where a dummy opening having a circular shape is defined in each of the terminal parts. A clamp groove partially recessed in a direction of the center part from an end of the terminal part is defined in each of the terminal parts, the clamp groove and the dummy opening are aligned with each other in the first direction, and a radius of the dummy opening may be smaller than or equal to a half of a width of the clamp groove in a second direction crossing the first direction.

This application claims priority to Korean Patent Application No. 10-2024-0112786, filed on Aug. 22, 2024, and all the benefits accruing therefrom under 35 U.S.C. § 119, the content of which in its entirety is herein incorporated by reference.

### BACKGROUND

### (1) Field

The present disclosure herein relates to a mask and a mask assembly including the mask, and more particularly, to a mask with an opening for allowing a deposition material to be deposited on a substrate.

### (2) Description of the Related Art

Display devices may be manufactured through various processes. For example, a deposition process may be used during manufacture processes of display devices. In a deposition process for manufacturing display devices, a mask may be adhered to a deposition substrate to deposit materials.

A light emitting display device generally includes a light emitting element disposed in each pixel. The light emitting element includes a light emitting pattern disposed between electrodes spaced apart from each other. The light emitting pattern included in each pixel may be classified into a plurality of groups.

### SUMMARY

In a manufacturing process of a display device, a mask may be used to deposit pixels onto a deposition substrate. However, when the size of the mask becomes larger, the mask itself may be deformed, and thus insufficiently adhered to the substrate.

The present disclosure provides a mask with reduced wave deformation.

The present disclosure also provides a mask assembly including a mask with reduced wave deformation.

An embodiment of the invention provides a mask including a center part including a cell region having deposition openings defined therein and extending along a first direction, and terminal parts spaced apart from each other in a first direction with the center part therebetween, and each having a circular dummy opening defined therein.

In an embodiment, a clamp groove partially recessed in a direction of the center part from an end of the terminal part may be defined in each of the terminal parts.

In an embodiment, the clamp groove and the dummy opening are aligned with each other in the first direction.

In an embodiment, a radius of the dummy openings may be smaller than or equal to a half of a width of the clamp groove in a second direction crossing the first direction.

In an embodiment, the clamp groove may have a U-shape defined by a curvature part and straight parts extending from the curvature part.

In an embodiment, a center of curvature of the curvature part may be aligned with a center of the dummy opening in the first direction.

In an embodiment, in a plan view, the curvature part may have a semicircular shape protruding toward the center part, and each of the straight parts may extend in the first direction from an end of the curvature part.

In an embodiment, a radius of curvature of the curvature part may be greater than or equal to the radius of the dummy opening.

In an embodiment, the clamp groove may have a symmetrical form with respect to an imaginary symmetry line extending in the first direction through the center of curvature of the curvature part and the center of the dummy opening.

In an embodiment, a protrusion may be defined in each of the terminal parts, and the protrusion may include a first protrusion defined as a portion between straight parts opposed to each other in the second direction, among the straight parts included in different clamp grooves in respective terminal parts, and a second protrusion defined, among the straight parts included in different clamp grooves in the respective terminal parts, as a portion of the terminal part positioned at a right side of a rightmost straight part, or as a portion of the terminal part positioned at a left side of a leftmost straight part.

In an embodiment, the protrusion may not overlap the dummy opening in both the first direction and the second direction.

In an embodiment, the dummy opening and the clamp groove may be each provided in plurality in each of the terminal parts, and the dummy opening and the clamp grooves may be arranged in a one-to-one correspondence with each other.

In an embodiment, the numbers and the radii of the dummy openings defined in one of the terminal parts may be the same as radii and numbers of the dummy openings defined in another one of the terminal parts.

In an embodiment, the dummy openings defined in one of the terminal parts and the dummy openings defined in another one of the terminal parts may be respectively aligned with each other in the first direction.

In an embodiment, the dummy openings defined in one of the terminal parts and the dummy openings defined in another one of the terminal parts may be in a one-to-one correspondence with each other in the first direction, and centers of the corresponding dummy openings may be aligned with each other in the first direction.

In an embodiment, in a plan view, the clamp grooves may have a same shape as each other and be spaced apart from each other at equal intervals in the second direction, the dummy openings may have a same shape as each other and be spaced apart at equal intervals in the second direction, and the clamp grooves and the dummy openings may be spaced apart from each other in the first direction.

In an embodiment, in a plan view, an area of the dummy opening may be greater than an area of the deposition opening.

In an embodiment, the boundary lines between the terminal parts and the center part may be defined as cutting lines, welding points may be defined between respective cutting lines and the deposition openings, and the welding points may be spaced apart from an adjacent dummy opening with the cutting line therebetween.

In an embodiment of the invention, a mask assembly includes a mask frame with a frame opening defined therein, and masks including a center part extending in a first direction with deposition openings defined therein, and terminal parts spaced apart from each other in the first direction with the center part therebetween, where dummy openings each having a circular shape is defined in the terminal parts not to overlap the frame opening, and, the masks are arranged on the masks frame in a second direction crossing the first direction.

In an embodiment, a clamp groove partially recessed toward the center part from an end of the terminal part is defined in each of the terminal parts, the clamp groove and the dummy opening part are arranged in the first direction, and a radius of the dummy opening may be smaller than or equal to a half of a width of the clamp groove in the second direction.

In an embodiment, the boundary lines between the terminal parts and the center part may be defined as cutting lines.

In an embodiment, welding points may be defined between respective cutting lines and the deposition openings.

In an embodiment, the welding points may be spaced apart from adjacent dummy openings with the cutting line therebetween.

In an embodiment, the clamp groove may include a curvature part and a straight part, and a center of curvature of the curvature part may be aligned with a center of the dummy opening in the first direction.

In an embodiment, in a plan view, the curvature part may have a semicircular shape protruding toward the center part, and a radius of curvature of the curvature part may be greater than or equal to the radius of the dummy opening.

In an embodiment, a protrusion may be defined as a portion between straight parts opposed to each other along the second direction, among the straight parts included in different clamp grooves in respective terminal parts, and the protrusion may not overlap the dummy opening in the first direction.

In an embodiment, in a plan view, the dummy opening may be defined in an outside of the frame opening.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The above and other features of embodiments of the invention will become more apparent by describing in further detail embodiments thereof with reference to the accompanying drawings, in which:

FIG. 1 is a cross-sectional view of a deposition device according to an embodiment of the invention;

FIG. 2 is a perspective view of a mask assembly according to an embodiment of the invention;

FIG. 3 is an exploded perspective view of a mask assembly according to an embodiment of the invention;

FIG. 4 is a plan view of a mask according to an embodiment of the invention;

FIG. 5 is an enlarged view of a part of a mask;

FIG. 6 is an enlarged view of region AA′ in FIG. 5;

FIG. 7 is a plan view of a mask according to an embodiment of the invention;

FIG. 8 illustrates a simulation of wave occurrence degree of a mask according to Comparative Example;

FIGS. 9 to 11 show simulations of wave deformations of masks according to the invention;

FIG. 12 shows a simulation of wave deformation of a mask according to Comparative Example;

FIG. 13 is a graph showing simulation results of the masks shown in FIGS. 9 to 12;

FIG. 14 is a perspective view of a display panel according to an embodiment of the invention; and

FIG. 15 is a cross-sectional view of a display panel according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present. In this specification, it will be understood that when an element (or a region, a layer, a portion, or the like) is referred to as being “connected to” or “coupled to” another element or layer, it can be directly connected or coupled to the other element or layer or intervening elements may be disposed therebetween.

Like numerals or symbols refer to like elements throughout. Also, in the drawings, the thicknesses, ratios, and dimensions of the elements are exaggerated for effective description of the technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. Also, the terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

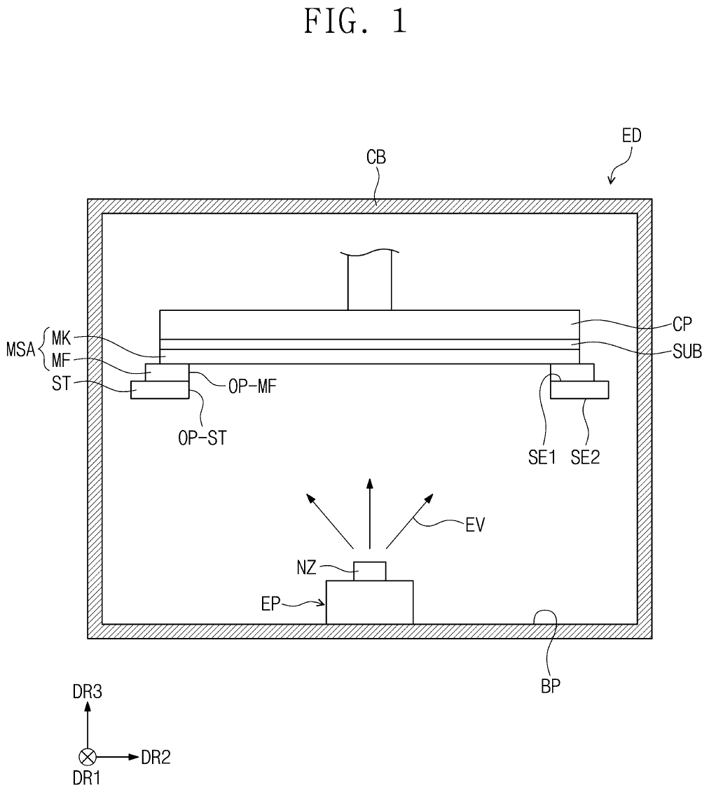

FIG. 1 is a cross-sectional view of a deposition device according to an embodiment of the invention.

Referring to FIG. 1, deposition device ED according to an embodiment may include a chamber CB, a fixing member CP, a mask assembly MSA, a stage ST, a deposition source EP, and a nozzle NZ. Although not illustrated separately, the deposition device ED may further include an additional mechanical device for configuring an inline system, in addition to the above components.

Also, the deposition device ED according to an embodiment may further include a coupling member. The coupling member may be fixed to a side wall of the chamber CB, and the stage ST may be connected to the coupling member and fixed stably inside the chamber CB. Thus, a deposition process may be performed stably even when the stage ST is disposed vertically.

The chamber CB may provide an internal space. The deposition source EP, the mask assembly MSA, and the stage ST may be disposed in the internal space of the chamber CB. The chamber CB may form or define a sealed space. The internal space of the chamber CB may provide a vacuum deposition condition. The chamber CB may have at least one gate, and the chamber CB may be opened and closed through the gate. A mask MK, a mask frame MF, and a substrate SUB may enter and exit the chamber CB via the gate.

The chamber CB may include a floor surface BP, a ceiling surface, and side walls. The floor surface BP of the chamber CB may be parallel to a plane defined by a first direction DR1 and a second direction DR2, and a normal direction of the floor surface BP of the chamber CB may be parallel to a third direction DR3.

The fixing member CP may be disposed inside the chamber CB and face deposition source EP in the third direction DR3. The fixing member CP may allow the substrate SUB to adhere to the mask MK. The fixing member CP may include magnetic substances for adhering the mask MK and the substrate SUB. In an embodiment, for example, the magnetic substances may generate magnetic force and effectively prevent the mask MK from being bent. However, an embodiment of the invention is not limited thereto, and the fixing member CP may include a jig or a robot arm for holding the mask MK.

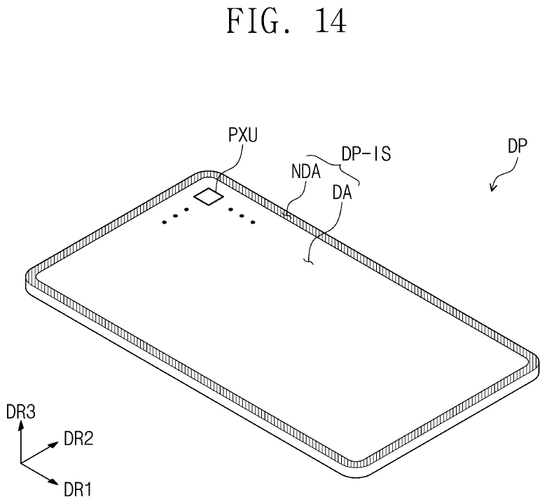

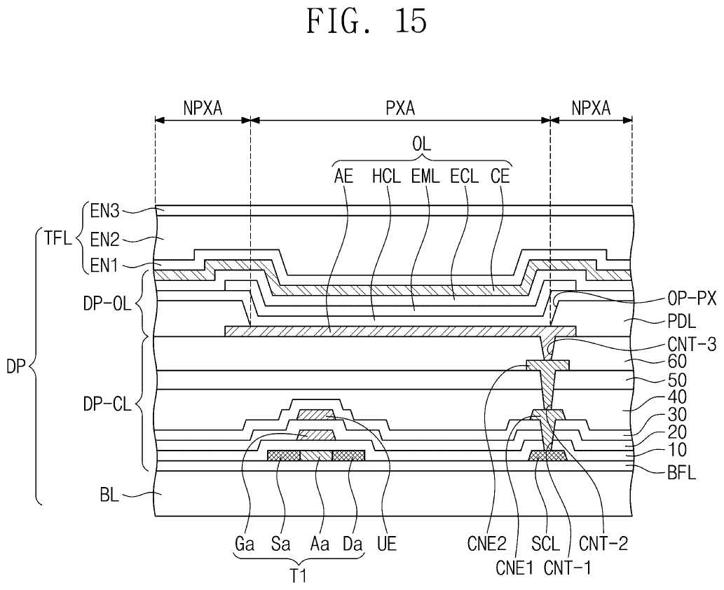

The substrate SUB may be disposed between the mask MK and the fixing member CP. The substrate SUB may be an object to be processed on which a deposition material is to be deposited. The substrate SUB may include a support substrate and a base layer BL (see FIG. 15). Depending on the structure formed through deposition process, the substrate SUB may also include some components of the display panel DP (see FIG. 14) formed on the base layer BL (see FIG. 15).

The deposition source EP may be disposed inside the chamber CB and may face the fixing member CP in the third direction DR3. The deposition source EP may include a storage space for storing a deposition material EV and at least one nozzle NZ. The deposition material EV may include a sublimable or evaporable inorganic material, metal, or organic material. In an embodiment, for example, the deposition material EV may include an organic light emitting material for forming a light emitting layer EML (see FIG. 15) of the display panel DP (see FIG. 15).

The sublimated or evaporated deposition material EV may be sprayed toward the substrate SUB through the nozzle NZ. The deposition material EV may pass through the deposition openings OP-MK of the mask MK and may be deposited in a pattern on the substrate SUB.

The stage ST may be disposed between the deposition source EP and the fixing member CP. The stage ST may support the rear surface of the mask frame MF, and may be disposed in a movement path of the deposition material EV which is supplied to the substrate SUB from the deposition source EP. The stage ST may include a stage opening OP-ST. The deposition material EV may be provided to the mask MK through the stage opening OP-ST. Coupling grooves for fixing the above-stated coupling member may be defined at the corners of the stage ST. The stage ST may be fixed to the coupling member through the coupling grooves in a bolt-fastening manner.

The stage ST may include a seating surface SE1 on which the mask frame MF is seated and a rear surface SE2 opposed to the seating surface SE1. The seating surface SE1 and the rear surface SE2 of the stage ST may each be provided substantially parallel to the first direction DR1 and the second direction DR2. Each of the rear surfaces of mask frame MF and the mask MK are provided substantially parallel to the floor surface BP of the chamber CB and horizontal deposition process may be proceeded.

However, an embodiment of the invention is not limited thereto, and in another embodiment, the seating surface SE1 and the rear surface SE2 of the stage ST may be provided substantially vertical to the floor surface BP of the chamber CB such that the mask MK having a large surface area may be effectively prevented from sagging due to gravity during a vertical deposition process, and improve deposition reliability.

The mask frame MF may be disposed on the stage ST. The mask frame MF may be provided in a rectangular frame shape when viewed in a plan view or in a thickness direction. The mask frame MF may include an upper surface facing the mask MK, a rear surface opposed to the upper surface and facing the seating surface SE1 of stage ST, and side surfaces connected between the upper surface and the rear surface.

A frame opening OP-MF overlapping stage opening OP-ST may be defined in the mask frame MF. As will be described later, the deposition material EV may pass through the frame opening OP-MF and be provided to the mask MK.

The mask frame MF may function to support the mask MK. The mask frame MF may have a predetermined rigidity. The mask frame MF may include a metal material such as stainless steel (SUS), invar, nickel (Ni), or cobalt (Co).

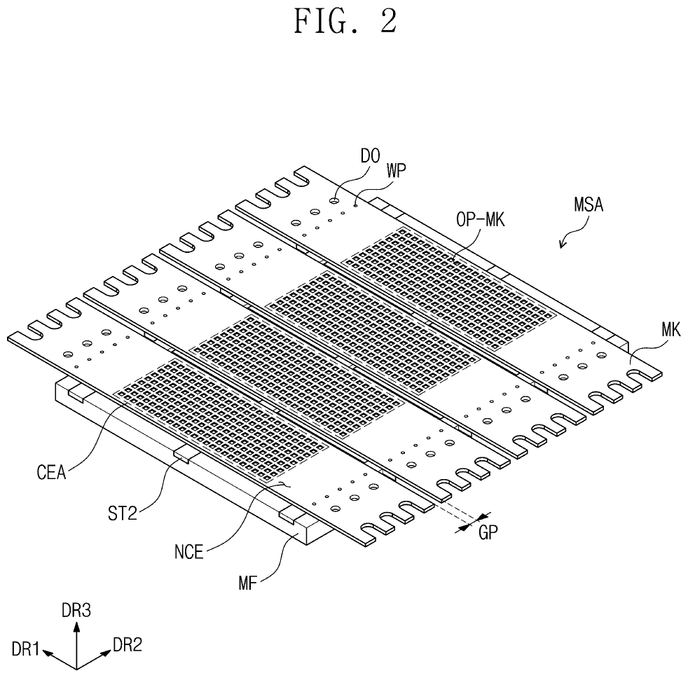

The mask MK may be disposed between the substrate SUB and the mask frame MF. The deposition openings OP-MK (see FIG. 2) overlapping the frame opening OP-MF may be defined in the mask MK, and the deposition material EV may be deposited in a pattern on the substrate SUB by passing through the deposition openings OP-MK (see FIG. 2). This will be described later in greater detail.

The mask MK may be provided in plurality and be disposed on the mask frame MF. The masks MK may be coupled to the mask frame MF. In an embodiment, for example, the masks MK may be coupled to the mask frame MF through a welding process.

In an embodiment, for example, one end and the other end of each of the masks MK may be disposed on the mask frame MF and subjected to the welding process, thereby coupling the masks MK and the mask frame MF to each other. Welding projections may be formed on the one end and the other end of each of the masks MK by the welding process. The mask MK may be a fine metal mask. The Mask MK may include a magnetic material. In an embodiment, for example, the mask MK may include Invar, which is a nickel-iron alloy (FeNi36 or 64FeNi).

In a typical deposition mask, the “mask sagging phenomenon”, in which the mask bends downwards due to gravity, typically occurs, and when the deposition process is performed in a state of the mask being bent due to the mask sagging phenomenon, the reliability of the deposition process is reduced because the mask is insufficiently adhered to the substrate.

Thus, welding may be performed while both sides of the mask are being gripped by a clamp to allow a tensile force to be applied in the extending direction of the mask. However, this causes a “wave deformation” to occur on the mask to result in a decrease in the reliability of the deposition process. In this specification, the “wave deformation” may indicate a deformation in which the height of the mask varies along a direction crossing the extension direction of the mask. The wave deformation may also be described as a “wrinkling deformation”.

According to an embodiment of the invention, the mask MK with reduced “wave deformation” may be provided by defining a dummy opening DO (see FIG. 2). Thus, a gap may be formed between the mask MK and the substrate SUB and the occurrence of deposition defects may thus be reduced. Hereinafter, by referring to the drawings, description will be focused on a structure of a mask MK having a dummy opening DO (see FIG. 2) defined therein, and a structure of a mask assembly MSA including the mask MK.

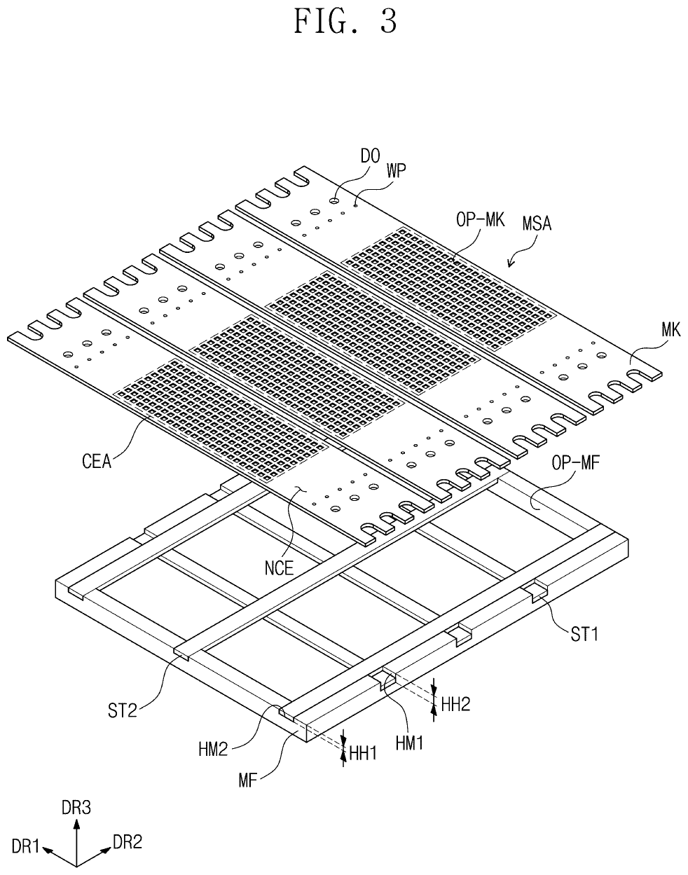

FIG. 2 is a perspective view of a mask assembly according to an embodiment of the invention. FIG. 3 is an exploded perspective view of the mask assembly according to an embodiment of the invention.

Referring to FIGS. 2 and 3, the mask assembly MSA according to an embodiment may include a mask frame MF, a first stick ST1, a second stick ST2 and a mask MK.

The first stick ST1 may be disposed on the mask frame MF. The first stick ST1 may overlap the frame opening OP-MF. The first stick ST1 may extend in the first direction DR1. The first stick ST1 may be provided in plurality. The first stick ST1 may be arranged in the second direction DR2.

A middle portion of the first stick ST1 may overlap the frame opening OP-MF, and a terminal portion may overlap the mask frame MF or protrude to the outside of the mask frame MF.

The second stick ST2 may be disposed on the first stick ST1. That is, the second stick ST2 may be disposed between the mask MK and the first stick ST1. However, the arrangement relationship of the first stick ST1 and the second stick ST2 is not limited thereto, and the first stick ST1 may be disposed between the second stick ST2 and the mask MK.

The second stick ST2 may overlap the frame opening OP-MF. The second stick ST2 may extend in the second direction DR2. The second stick ST2 may be provided in plurality. The second sticks ST2 may be arranged in the first direction DR1.

The masks MK may be spaced apart, by a mask gap GP, from each other in the second direction DR2. Referring to FIGS. 2 and 3, the first sticks ST1 may be disposed under the mask gaps GP. On a plane or when viewed in a plan view, the mask gaps GP may be blocked by the first sticks ST1.

In an embodiment, one of the first stick ST1 and the second stick ST2 may be a short-side stick, and the other of the first stick ST1 and the second stick ST2 may be a long-side stick. In an embodiment, a length of the first stick ST1 extending in the first direction DR1 may be smaller than a length of the second stick ST2 extending in the second direction DR2. In such an embodiment, the first stick ST1 may be a short-side stick, and the second stick ST2 may be a long-side stick.

Stick grooves HM1 and HM2 may be defined or formed in the mask frame MF by partially recessing the top surface. An end of the first stick ST1 may be disposed on the first stick groove HM1. An end of the second stick ST2 may be disposed on the second stick groove HM2. The stick grooves HM1 and HM2 may be designed or configured to correspond to the positions where the sticks ST1 and ST2 are to be positioned, and may function to fix the sticks. In an embodiment, a short-side stick may be disposed under a long-side stick. Referring to FIG. 3, the first stick groove HM1 may be recessed by a second depth HH2 with respect to the top surface of the mask frame MF, and the second stick groove HM2 may be recessed by a first depth HH1 with respect to the top surface of the mask frame MF. Here, the second depth HH2 may be greater than the first depth HH1.

The second stick ST2 may be in contact with the rear surfaces of the masks MK. The first sticks ST1 may not be in contact with the masks MK. The first sticks ST1 may be spaced apart from the masks MK with the second sticks ST2 therebetween. The distances between the first sticks ST1 and the masks MK spaced apart may correspond to thicknesses of the second sticks ST2.

Some of the second sticks ST2 may overlap an active region CEA. Thus, some of the second sticks ST2 may partially block the deposition material EV (see FIG. 1) from passing through the frame opening OP-MF and the deposition opening OP-MK and being deposited on the substrate SUB (see FIG. 1). FIG. 2 illustrates an embodiment where the second stick ST2, which is disposed second among the three second sticks ST2 arranged in the first direction DR1, blocks a portion of the active region CEA. However, an embodiment of the invention is not limited to what is illustrated in the drawing, and a plurality of the second stick ST2 may block the active region CEA, or the second stick ST2 may not block the active region CEA.

The sticks ST1 and ST2 may each include a nonmagnetic material. In an embodiment, for example, the sticks ST1 and ST2 may each include aluminum, However, this is an example of a material of the first stick ST1 and the second stick ST2, and an embodiment of the invention is not limited thereto.

The mask MK may be disposed on the sticks ST1 and ST2. The mask MK may extend in the first direction DR1. The mask MK may be provided in plurality. The masks MK may be arranged in the second direction DR2.

The mask MK may include (or be divided into) an active region CEA and a non-active region NCE. In this disclosure, the non-active region NCE may be the remaining area of the mask MK excluding the active region CEA.

The non-active region NCE may surround the active region CEA. The deposition openings OP-MK may be defined in the active region CEA of the mask MK. The deposition openings OP-MK may be formed through the mask by penetrating the mask MK from the top surface to the bottom surface of the mask MK. That is, the deposition openings OP-MK may be provided by completely penetrating the mask MK in the third direction DR3.

The mask MK according to an embodiment of the invention may reduce the degree of “wave deformation” occurring therein by forming a dummy opening DO, which disperses the stress generated during which the mask MK is stretched and welded, and by designing the position, quantity, and shape of the dummy opening. Hereafter referring to FIGS. 4 to 7, a structure of the mask MK with reduced wave deformation will be described.

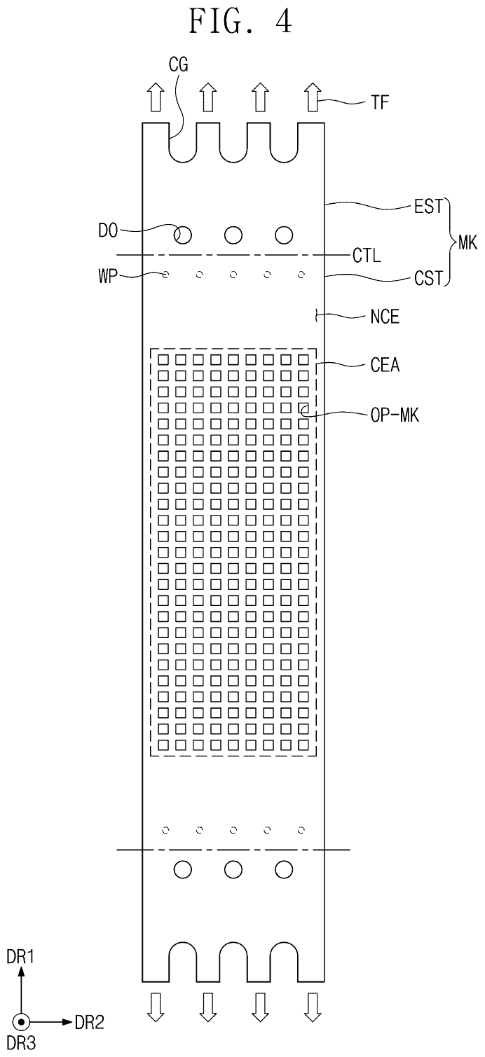

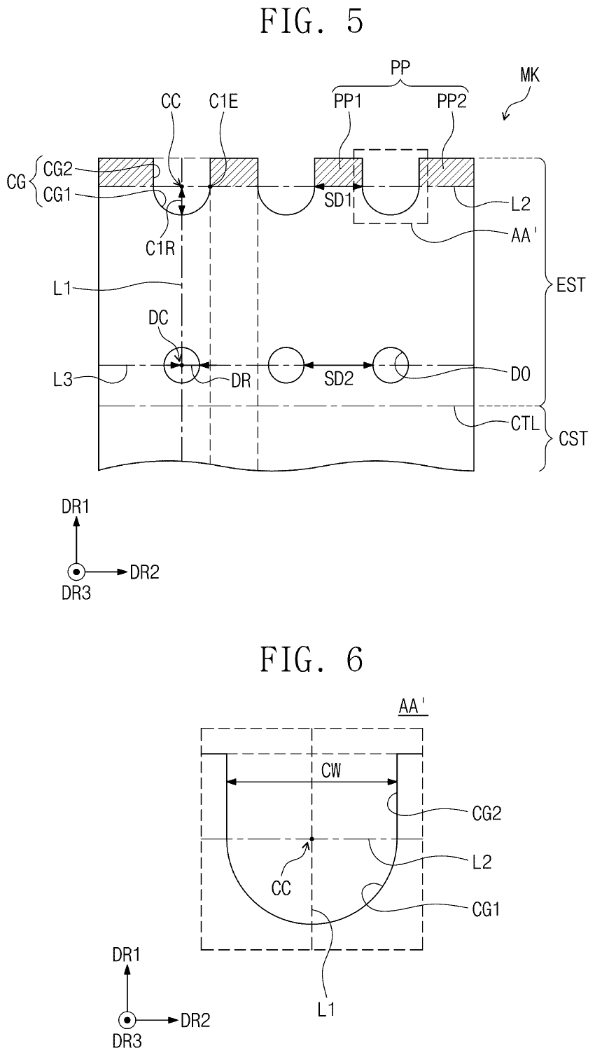

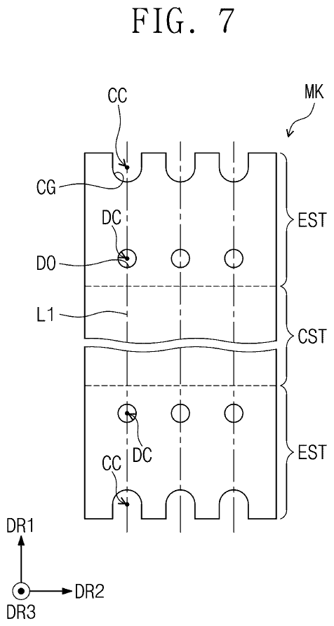

FIG. 4 is a plan view of a mask according to an embodiment of the invention. FIG. 5 is an enlarged view of a part of a mask according to an embodiment of the invention. FIG. 6 is an enlarged view of region AA′ in FIG. 5. FIG. 7 is a plan view of a mask according to an embodiment of the invention.

FIG. 4 illustrates an example in which a tensile force TF is applied in the extension direction of the mask MK. Here, the tensile force TF applied to the mask MK may be provided by gripping, by a clamp or the like, a protrusion PP (see FIG. 5) to be described later.

Referring to FIG. 4, the mask MK according to an embodiment may include a center part CST and a terminal part EST.

The boundary between the center part CST and the terminal part EST may be defined based on a cutting line CTL. The cutting line CTL may correspond to the position where the mask MK is cut after the mask MK is welded to the mask frame MF (see FIG. 3).

An active region CEA and a welding point WP may be defined in the center part CST. A non-active region NCE may be defined as the remaining area of the mask MK excluding the active region CEA on a plane.

The welding points WP may be defined in the center part CST. The welding points WP may correspond to the positions where mask MK is welded and fixed onto the mask frame MF so that a gap is not formed in the mask MK during the deposition process.

The welding points WP may be defined between respective cutting lines CTL and the deposition openings OP-MK. The welding points WP may be defined between the cutting lines CTL and the cell region CEA. The welding points WP may be spaced apart from the adjacent dummy openings DO with the cutting lines CTL therebetween. FIG. 4 illustrates ten welding points WP in circular shape with dotted lines. However, this is illustrated as an example, and the number and shape of the welding points WP is not particularly limited thereto.

The terminal parts EST may be defined as being spaced apart from each other in the direction in which the center part CST extends. FIG. 4 illustrates as an embodiment where the center part CST of the mask MK extends in the first direction DR1, and the terminal parts EST are spaced apart from each other in the first direction DR1.

The dummy openings DO may be defined in the terminal parts EST. On a plane, the dummy openings DO may each have a circular shape. FIG. 4 illustrates as an example that the terminal parts EST each have three dummy openings DO defined therein. However, the number of the dummy openings DO is not particularly limited thereto as long as the dummy openings DO are in a one-to-one correspondence with the clamp grooves CG to be described later.

On a plane, the dummy openings DO may be defined outside the frame opening OP-MF (see FIG. 3). The dummy openings DO may not overlap the frame opening OP-MF (see FIG. 3). Thus, unlike the deposition opening OP-MK, the dummy openings DO may not be used in deposition of the substrate SUB, and may function to prevent the “wave deformation” of the mask MK during the welding process.

The clamp groove CG may be defined at an end of each of the terminal parts EST. The clamp groove CG may have a U-shape in which an end of each of the terminal parts EST is recessed toward the center part CST.

The clamp groove CG may be defined in plurality in each of the terminal parts EST. The clamp grooves CG may have a same shape as each other, and be spaced apart from each other in the second direction DR2. FIG. 4 illustrates an embodiment where the number of the clamp grooves CG defined in each of the terminal parts EST is three, but the number of the clamp grooves CG is not limited to what is illustrated in the drawing.

The dummy opening DO may be defined in plurality in each of the terminal parts EST. The dummy openings DO may have a same shape as each other and be spaced apart from each other in the second direction DR2. The numbers of the dummy openings DO defined in the respective terminal parts EST may be equal to each other. That is, the number of the dummy openings DO defined in one of the terminal parts EST may be the same as the number of dummy openings DO defined in the other one of the terminal parts EST. FIG. 3 illustrates as an embodiment where the number of dummy openings DO defined in each of the terminal parts EST is three. However, the number of the dummy openings DO is not limited to what is illustrated in the drawing.

In an embodiment, the planar area of the dummy opening DO may be greater than that of the deposition opening OP-MK. However, an embodiment of the invention is not limited thereto.

There may be a certain positional relationship and morphological relationship between the clamp grooves CG and the dummy openings DO defined in each of the terminal parts EST. In an embodiment, for example, the number of the clamp grooves CG and the number of the dummy openings DO defined in each of the terminal parts EST may be the same as each other, and may be aligned in the first direction DR1.

The morphological and arrangement relationship between the clamp grooves CG and the dummy openings DO will be described in detail with reference to FIGS. 5 to 7.

FIG. 5 is an enlarged view of a portion of one terminal part EST and the center part CST. FIG. 6 is an enlarged view of one clamp groove CG.

Referring to FIGS. 5 and 6 together, in an embodiment, the clamp groove CG may include a curvature part CG1 and a straight part CG2. When seen on a plane or when viewed in a thickness direction (or the third direction DR3), the clamp groove CG may have a U-shape having the curvature part CG1 and the straight parts CG2 extending from the curvature part CG1. In an embodiment, for example, the curvature part CG1 may have a ‘semicircular shape’ protruding toward the center part CST on a plane. The radius of the semicircular shape may be defined as a “radius of curvature C1R”. Also, on a plane, a “center of curvature CC” of the curvature part CG1 may be defined.

On a plane, the straight parts CG2 may have shapes extending from respective ends C1E of the curvature part CG1 along the extension direction of the mask MK. In an embodiment, the straight parts CG2 may each extend from the ends C1E of the curvature part CG1 in the first direction DR1.

The straight parts CG2 may extend in the first direction DR1 and be parallel to each other. The distance between the straight parts CG2 in the second direction DR2 may be defined as a “width CW” of the clamp groove CG.

Referring to FIG. 5, the dummy opening DO defined on a side surface of the mask MK may have a “circle” shape on a plane. The center of the dummy opening DO may be defined as the center of the circle, and the radius of the dummy opening DO may be defined as the radius of the circle. In the disclosure, the center of the circle may be described as a “dummy center DC”, and the radius may be described as a “dummy radius DR”.

The mask MK according to an embodiment may significantly reduce or effective prevent the “wave deformation” that may occur in the mask MK by establishing a certain positional relationship and a morphological relationship between the dummy openings DO and the clamp grooves CG.

In an embodiment, as for the positional relationship between the clamp grooves CG and the dummy openings DO by referring to FIG. 5, the clamp grooves CG and the dummy openings DO may be aligned in the first direction DR1, that is, centers thereof are on a same straight imaginary line extending in the first direction DR1. In an embodiment, the clamp grooves CG and the dummy openings DO may be aligned with each other in a one-to-one correspondence in the first direction DR1. In the disclosure, the wording, the clamp grooves CG and the dummy openings DO have “a relationship in a one-to-one correspondence with each other in a certain direction” may indicate that the number of dummy openings DO aligning with one of the clamp grooves CG in the first direction DR1 is limited to one. Also, the clamp groove CG and the dummy opening DO corresponding to each other may be spaced apart in the first direction DR1.

In an embodiment, the dummy center DC may be aligned with the center of curvature CC in the first direction DR1. Thus, a first imaginary line L1 which passes through the center of curvature CC and the dummy center DC and which is parallel to the first direction DR1 may be defined.

The clamp groove CG may have a symmetrical form with respect to the first imaginary line L1, which is an imaginary symmetry line extending through the center of curvature CC and the dummy center DC in the first direction DR1.

In an embodiment, as for the morphological relationship between the clamp grooves CG and the dummy openings DO by referring to FIG. 5, the dummy radius DR may be smaller than or equal to a half of the width CW of the clamp groove CG. Also, the dummy radius DR may be smaller than or equal to the radius of curvature C1R. Thus, the dummy openings DO may not overlap the protrusion PP in the first direction DR1. This will be described later.

In each of the terminal parts EST, a certain positional relationship and a morphological relationship between the clamp grooves CG may also be established.

The centers of curvature CC may be aligned with each other in the second direction DR2, that is, centers thereof are on a same straight imaginary line extending in the second direction DR2. Referring to FIG. 5, a second imaginary line L2, which passes through the centers of curvature CC and which is parallel to the second direction DR2, may be defined.

The clamp grooves CG may be spaced apart from each other at equal intervals in the second direction DR2. Here, intervals of the clamp grooves CG may mean intervals between the centers of the curvature parts CG1 of the clamp grooves CG. FIG. 5 illustrates an embodiment where the clamp grooves CG are equally spaced apart at first intervals SD1 as an example.

The clamp grooves CG may have a same U-shape.

In each of the terminal parts EST, a certain positional relationship and a morphological relationship between the dummy openings DO may also be established.

The dummy centers DC may be aligned with each other in the second direction DR2, that is, the dummy centers DC are on a same straight imaginary line extending in the second direction DR2. Referring to FIG. 5, a third imaginary line L3, which passes through the dummy centers DC and which is parallel to the second direction DR2, may be defined.

The dummy openings DO may be spaced apart from each other at equal intervals in the second direction DR2. Here, intervals of the dummy openings DO may mean intervals between the dummy centers DC. FIG. 5 illustrates an embodiment where the dummy openings DO are equally spaced apart at second intervals SD2 as an example.

The dummy openings DO may have a same “circular” shape as each other.

The protrusion PP may be defined at an end of each of the terminal parts EST. For the convenience of illustration, FIG. 5 illustrates that a region in which the protrusion PP is defined is shown by hatching.

The protrusion PP may include a first protrusion PP1 and a second protrusion PP2.

The first protrusion PP1 may be defined as a portion between the straight parts CG2 opposed to each other along the second direction DR2, among the straight parts CG2 which are included in different clamp grooves CG in each of the terminal parts EST.

The second protrusion PP2 may be defined as a portion of the terminal part EST positioned at the right side of the straight part CG2 positioned at the rightmost side among the straight parts CG2 included in different clamp grooves CG, or as a portion of the terminal part EST positioned at the left side of the straight part CG2 positioned at the leftmost side in each of the terminal parts EST.

The protrusion PP may not overlap the dummy openings DO in both the first direction DR1 and the second direction DR2.

FIG. 7 is a plan view of a mask MK in which a portion of the center part CST is omitted. Hereinafter, by referring to FIG. 7, a positional relationship and a morphological relationship of the clamp grooves CG and the dummy openings DO which are included in different terminal parts EST will be described.

The dummy openings DO defined in one of the terminal parts EST of the mask MK and the dummy openings DO defined in the other one of the terminal parts EST of the mask MK may respectively be in a one-to-one correspondence with each other in the first direction DR1. That is, the number of the dummy openings DO, aligned in the first direction DR1 with one of the dummy openings DO defined in one terminal part EST, may be defined as one.

Here, the corresponding dummy centers DC in the mask MK may be aligned with each other in the first direction DR1. Referring to FIG. 7, when the first imaginary line L1 described with reference to FIG. 5 extends, the first imaginary line L1 may pass through not only the center of curvature CC and the dummy center DC defined in one of the terminal parts EST but also the dummy center DC defined in the other one of the terminal parts EST.

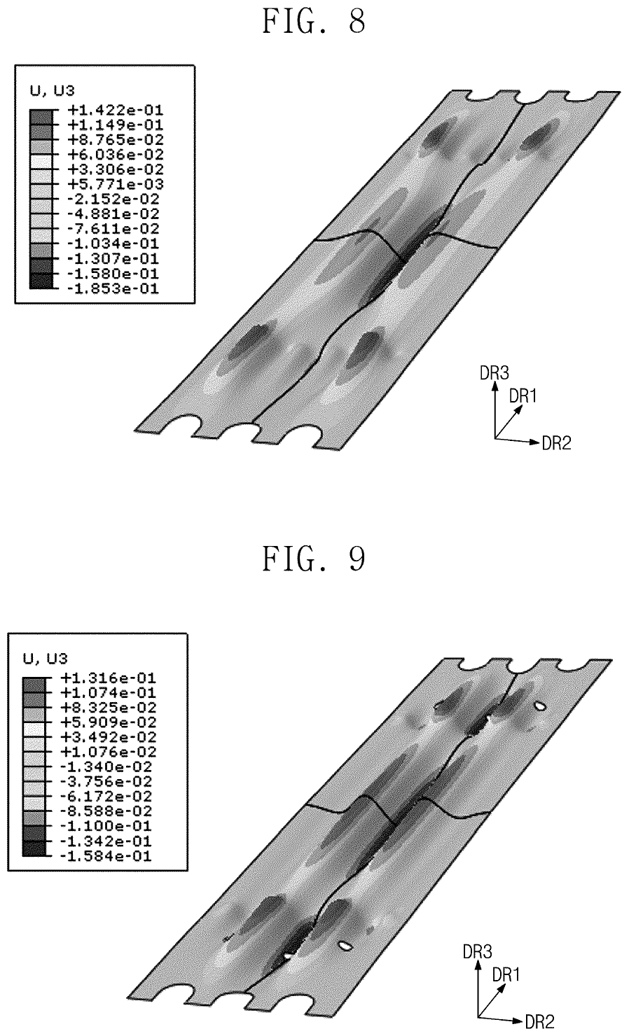

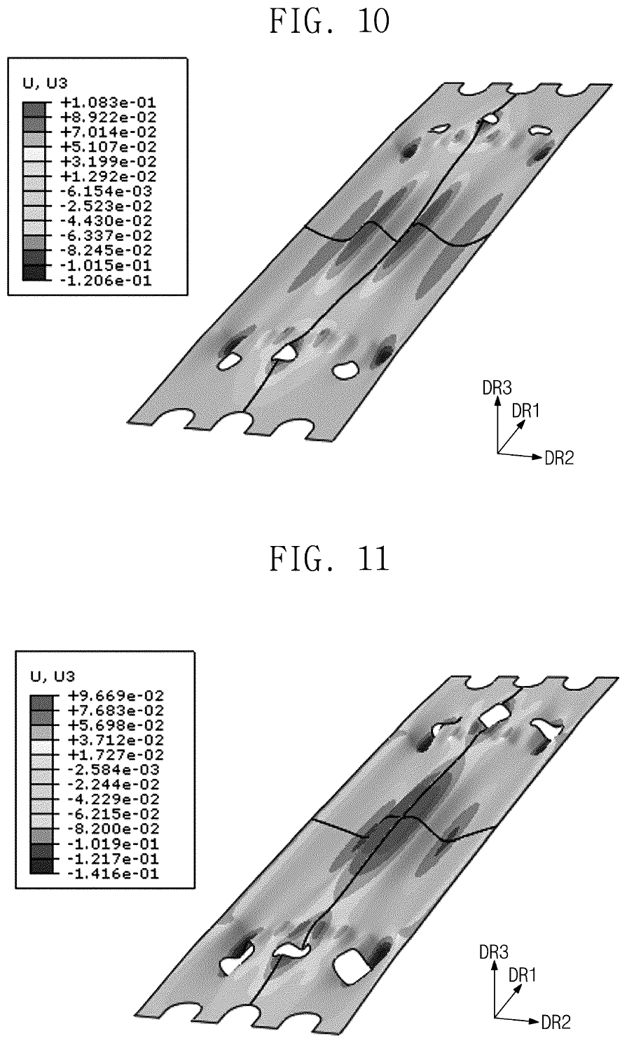

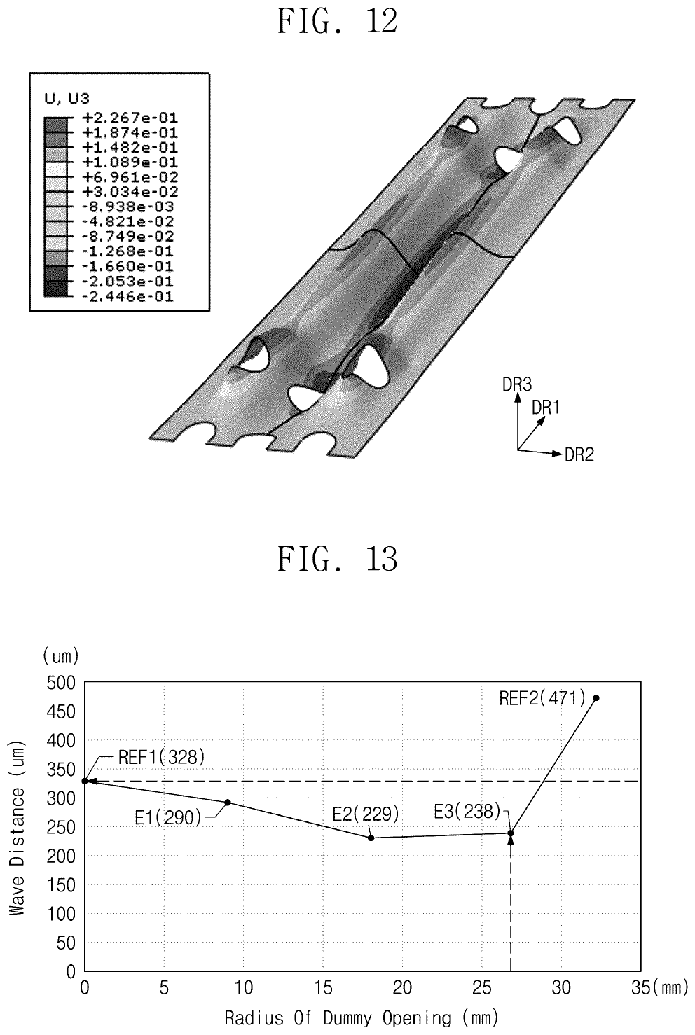

FIG. 8 illustrates a simulation of wave occurrence degree of a mask according to Comparative Example 1. FIGS. 9 to 11 show simulations of wave deformations of masks according to Examples 1 to 3 of the invention. FIG. 12 shows a simulation of wave deformation of a mask according to Comparative Example 2.

The masks illustrated in FIGS. 9 to 12 are masks in which dummy openings are additionally formed in the mask illustrated in FIG. 8.

A virtual tensile force was applied in the first direction DR1 to the masks illustrated in FIGS. 8 to 12. Specifically, the protrusion PP (see FIG. 5) may be gripped by a separate clamp and a tensile force may be applied parallel to the first direction DR1 in which the mask MK extends.

Thus, the “wave deformation” in which the height of the mask MK varies along the second direction DR2 occurred. With respect to the third direction DR3, a portion risen high is shown in a “red” color, and a portion sunk low is shown in a “blue” color. In the disclosure, the height difference between the highest risen portion and the lowest sunken portion of the mask in the third direction DR3 may be defined as a “wave distance”.

FIG. 13 is a graph showing simulation results of the masks shown in FIGS. 9 to 12. For the convenience of description, the numerical values of the wave distance are shown together with the simulation graph, and the measured numerical values of the wave distance are rounded to the tens place.

In the mask REF1 according to Comparative Example 1 illustrated in FIG. 8, only the clamp grooves may be defined, and the dummy openings may not be defined. Unlike Comparative Example 1, the dummy openings are defined in the masks E1, E2, and E3 according to Examples 1 to 3 illustrated in FIGS. 9 to 11 and the mask REF2 according to Comparative Example 2, and it is illustrated in an order that the dummy radius DR increases. Here, the mask E3 according to Example 3 is set in a way such that the radius of curvature CR (see FIG. 5) is equal to the dummy radius DR (see FIG. 5), and the mask REF2 according to Comparative Example 2 is set such that the dummy radius DR (see FIG. 5) is longer than the radius of curvature CR (see FIG. 5).

Hereinafter, ‘Table 1’ summarizes a comparison between the numerical values of the wave distance of the masks according to Examples and the mask according to Comparative Example 2, in which the dummy openings are formed, and the numerical values of the wave distance of the mask according to Comparative Example 1 in which the dummy opening is not formed.

In ‘Table 1’, “−” is added in front of the numerical value if the value is “decreased”, and “+” is added in front of the numerical value if the value is “increased”, compared to the numerical value of the wave distance of the mask according to Comparative Example 1.

TABLE 1

| | | | | Comparative |
|---|---|---|---|---|
| | Example 1 | Example 2 | Example 3 | Example 2 |
| Wave Distance (mm) | 290 | 229 | 238 | 471 |
| Difference from | −38 | −99 | −90 | +143 |
| Comparative Example | | | | |
| 1 (mm) | | | | |

Referring to FIG. 13 and Table 1, it may be confirmed that the wave distance is significantly reduced since the dummy openings DO (see FIG. 5) are formed in the mask according to Examples 1 to 3 (or embodiments of the invention). However, it may be confirmed that the wave distance is significantly increased in the mask according to Comparative Example 2, even though the dummy opening is provided therein. That is, it may be confirmed that the wave distance is significantly reduced when the dummy radius DR (see FIG. 5) is smaller than or equal to the radius of curvature CR (see FIG. 5), but the wave distance is significantly increased when the dummy radius DR (see FIG. 5) is greater than the radius of curvature CR (see FIG. 5).

The mask according to an embodiment of the invention may significantly reduce the wave distance by aligning the circular dummy openings with the clamp groove, and by providing the dummy radius smaller than or equal to the radius of curvature. That is, stress caused by a tensile force may be dispersed by optimizing the position and shape of the dummy opening and waves deformation may be effectively prevented from being continuously formed. Thus, in such an embodiment, the reliability of the deposition process using a mask may be improved.

FIG. 14 is a perspective view of a display panel according to an embodiment of the invention. FIG. 15 is a cross-sectional view of a display panel according to an embodiment of the invention.

A display panel DP illustrated in FIG. 14 may be the display panel DP manufactured using the mask MK, which is described above with reference to the FIGS. 1 to 13.

Referring to FIGS. 14 and 15, an embodiment of the display panel DP may display an image through a display surface DP-IS. The top surface of a member disposed on the topmost side of the display panel DP may be defined as the display surface DP-IS.

The display surface DP-IS may be parallel to a plane defined by the first direction DR1 and the second direction DR2. The normal direction of the display surface DP-IS, that is, the direction of thickness of the display panel DP, indicates the third direction DR3. A front surface (or a top surface) and a rear surface (or a bottom surface) of each layer or unit to be described below are distinguished based on the third direction DR3.

The display panel DP may include a display region DA and a non-display region NDA. A light emitting layer included in a pixel is disposed in the display region DA, and the light emitting layer of the pixel is not disposed in the non-display region NDA. The non-display region NDA is defined along the edge of the display surface DP-IS. The non-display region NDA may surround the display region DA. The non-display region NDA may be omitted or disposed only on one side of the display region DA in an embodiment of the invention.

Referring to FIG. 15, in an embodiment of the invention, the display panel DP may be a light emitting display panel. FIG. 15 illustrates a cross section corresponding to one of a plurality of pixels, and a cross section corresponding to one transiter T1 and a light emitting element OL.

The display panel DP includes a base layer BL, a circuit element layer DP-CL disposed on the base layer BL, a display element layer DP-OL disposed on the circuit element layer DP-CL, and an encapsulation layer TFL disposed on the display element layer DP-OL.

The base layer BL may include a synthetic resin layer. The base layer BL may be formed by forming a synthetic resin layer on a support substrate which is used during manufacture of the display panel DP, then forming a conductive layer and an insulation layer or the like on the synthetic resin layer, and removing the support substrate thereafter.

The circuit element layer DP-CL includes at least one insulation layer and a circuit element. The circuit element includes a signal line, a pixel driving circuit or the like. The circuit element layer DP-CL may be formed through a process of forming an insulation layer, a semiconductor layer, and a conductive layer by coating, depositing, etc., and through a process of patterning the insulation layer, the semiconductor layer, and the conductive layer by photolithography.

In an embodiment, the circuit element layer DP-CL may include a buffer layer BFL and first to sixth insulation layers 10, 20, 30, 40, 50, and 60. The first to sixth insulation layers 10, 20, 30, 40, 50, and 60 may include one of an inorganic film or an organic film. The buffer layer BFL may include an inorganic film. At least one of the fifth insulation layer 50 or the sixth insulation layer 60 may include an organic film.

FIG. 15 illustrates an arrangement relationship of an active Aa, a gate Ga, a source Sa, and a drain Da which constitutes a first transistor T1 in an embodiment.

The active Aa may include a polysilicon semiconductor. However, the active Aa is not limited thereto, and may include a metal oxide semiconductor. The source Sa and the drain Da are region which have a higher doping concentration than the active Aa, and may serve as an electrode.

The circuit element layer DP-CL may include first and second connection electrodes CNE1 and CNE2 which connect a signal line SCL and an anode AE. The first connection electrode CNE1 is connected to the signal line SCL through a first contact hole CNT-1, and the second connection electrode CNE2 is connected to the first connection electrode CNE1 through a second contact hole CNT-2. The anode AE is connected to the second connection electrode CNE2 through a third contact hole CNT-3.

The display element layer DP-OL may include a pixel-defining film PDL and a light emitting element OL. The light emitting element OL may be an organic light emitting diode or a quantum dot light emitting diode. The anode AE may be disposed on the sixth insulation layer 60. A pixel opening OP-PX of the pixel-defining film PDL may expose at least a portion of the anode AE. The pixel opening OP-PX of the pixel-defining film PDL may define a light emitting region PXA. A non-light emitting region NPXA may surround the light emitting region PXA.

A hole control layer HCL and an electrode control layer ECL may be disposed in common on the light emitting region PXA and the non-light emitting region NPXA. The light emitting layer EML may include a light emitting material, and may be provided in a pattern to correspond to the pixel opening OP-PX. In contrast to the hole control layer HCl and the electrode control layer ECL which are in the form of a film, the light emitting layer EML may be deposited through a different method. The hole control layer HCL and the electrode control layer ECL may be formed in common in a plurality of pixels using an open mask.

The light emitting layer EML may be formed through the mask assembly MSA described above with reference to FIG. 1. The deposition substrate BS, described in FIG. 1, may be defined as a structure in which the pixel-defining film PDL, the anode AE, and the hole control layer HCL are formed on the base layer BL described in FIG. 15.

A cathode CE may be disposed on the electrode control layer ECL. The encapsulation layer TFL may be disposed on the cathode CE. The encapsulation layer TFL may be a thin-film encapsulation layer for encapsulating the display element layer DP-OL. The encapsulation layer TFL may include a plurality of thin films. The plurality of thin films may include inorganic layers EN1, EN3 and an organic layer EN2. The encapsulation layer TFL may include an insulating layer for encapsulating the display element layer DP-OL and a plurality of insulation layers for improving light output efficiency.

According to an embodiment of the invention, a dummy opening included in a mask may effectively prevent a wave deformation of the mask and thus effectively prevent poor deposition from occurring.

An embodiment of the invention provides a mask assembly which effectively prevents a wave deformation of a mask and thus prevents poor deposition from occurring.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A mask comprising:
a center part extending in a first direction, and including a cell region in which deposition openings are defined; and
terminal parts spaced apart from each other in the first direction with the center part therebetween, wherein a dummy opening having a circular shape is defined in each of the terminal parts,
wherein a clamp groove partially recessed in a direction of the center part from an end of the terminal part is defined in each of the terminal parts,
the clamp groove and the dummy opening are aligned with each other in the first direction, and
a radius of the dummy opening is smaller than or equal to a half of a width of the clamp groove in a second direction crossing the first direction.

2. The mask of claim 1, wherein the clamp groove has a U-shape defined by a curvature part, and straight parts extending from the curvature part, and
a center of curvature of the curvature part is aligned with a center of the dummy opening in the first direction.

3. The mask of claim 2, wherein in a plan view, the curvature part has a semicircular shape protruding toward the center part, and each of the straight parts extends in the first direction from an end of the curvature part.

4. The mask of claim 2, wherein a radius of curvature of the curvature part is greater than or equal to the radius of the dummy opening.

5. The mask of claim 2, wherein the clamp groove has a symmetrical shape with respect to an imaginary symmetry line extending in the first direction through the center of curvature of the curvature part and the center of the dummy opening.

6. The mask of claim 2, wherein a protrusion is defined in each of the terminal parts, and
the protrusion comprises
a first protrusion defined as a portion between straight parts opposed to each other in the second direction, among the straight parts included in different clamp grooves in respective terminal parts, and
a second protrusion defined, among the straight parts included in different clamp grooves in the respective terminal parts, as a portion of the terminal part positioned at a right side of a rightmost straight part, or as a portion of the terminal part positioned at a left side of a leftmost straight part.

7. The mask of claim 6, wherein the protrusion does not overlap the dummy opening in both the first direction and the second direction.

8. The mask of claim 1, wherein the dummy opening and the clamp groove are each provided in plurality in each of the terminal parts, and
the dummy openings and the clamp grooves are arranged in a one-to-one correspondence with each other.

9. The mask of claim 8, wherein radii and numbers of the dummy openings defined in one of the terminal parts are the same as radii and numbers of the dummy openings defined in another one of the terminal parts.

10. The mask of claim 8, wherein the dummy openings defined in one of the terminal parts and the dummy openings defined in another one of the terminal parts are respectively aligned with each other in the first direction.

11. The mask of claim 8, wherein the dummy openings defined in one of the terminal parts and the dummy openings defined in another one of the terminal parts are in a one-to-one correspondence with each other in the first direction, and
centers of corresponding dummy openings are aligned with each other in the first direction.

12. The mask of claim 8, wherein in a plan view, the clamp grooves have a same shape as each other and are spaced apart from each other at equal intervals in the second direction,
the dummy openings have a same shape as each other and are spaced apart from each other at equal intervals in the second direction, and
the clamp grooves and the dummy openings are spaced apart from each other in the first direction.

13. The mask of claim 1, wherein in a plan view, an area of the dummy opening is greater than an area of the deposition opening.

14. The mask of claim 1, wherein boundary lines between the terminal parts and the center part are defined as cutting lines,
welding points are defined between respective cutting lines and the deposition openings, and
the welding points are spaced apart from an adjacent dummy opening with the cutting line therebetween.

15. A mask assembly comprising:
a mask frame with a frame opening defined therein;
masks including a center part extending in a first direction with deposition openings defined therein, and terminal parts spaced apart from each other in the first direction with the center part therebetween, wherein dummy openings each having a circular shape is defined in the terminal parts not to overlap the frame opening, and the masks are arranged on the mask frame in a second direction crossing the first direction,
wherein a clamp groove partially recessed in a direction of the center part from an end of the terminal part is defined in each of the terminal parts,
the clamp groove and the dummy opening are arranged in the first direction, and
a radius of the dummy opening is smaller than or equal to a half of a width of the clamp groove in the second direction.

16. The mask assembly of claim 15, wherein boundary lines between the terminal parts and the center part are defined as cutting lines,
welding points are defined between respective cutting lines and the deposition openings, and
the welding points are spaced apart from adjacent dummy openings with the cutting line therebetween.

17. The mask assembly of claim 15, wherein the clamp groove includes a curvature part and a straight part, and
a center of curvature of the curvature part is aligned with a center of the dummy opening in the first direction.

18. The mask assembly of claim 17, wherein in a plan view, the curvature part has a semicircular shape protruding toward the center part, and
a radius of curvature of the curvature part is greater than or equal to the radius of the dummy opening.

19. The mask assembly of claim 17, wherein protrusion is defined as a portion between straight parts opposed to each other along the second direction, among the straight parts included in different clamp grooves in respective terminal parts, and
the protrusion does not overlap the dummy opening in the first direction.

20. The mask assembly of claim 15, wherein in a plan view, the dummy opening is defined in an outside of the frame opening.
